(19) United States
(12) Patent Application Publication
(10) Pub. No.: US 2026/0031306 A1
(43) Pub. Date: Jan. 29, 2026

(54) SEMICONDUCTOR WAFER PROCESSING WITH ELECTROMAGNETIC PLASMA CONFINEMENT

(71) Applicant: Applied Materials, Inc., Santa Clara, CA (US)

(72) Inventors: Yogananda SARODE VISHWANATH, Bangalore (IN); John POULOSE, Sunnyvale, CA (US)

(21) Appl. No.: 18/787,734

(22) Filed: Jul. 29, 2024

(51) Int. Cl. H01J 37/32; H01L 21/02

(52) U.S. Cl. CPC H01J 37/32669; H01J 2237/332; H10P 14/6336

(57) ABSTRACT

A system and method for forming a film that includes generating a plasma in a processing volume of a processing chamber to form the film on a substrate. The processing chamber includes a plasma confinement system. The plasma confinement system includes a chamber wall liner having a ring shaped body. The chamber wall liner has an inner wall, a slit opening formed through the inner wall and sized for a substrate to pass therethrough the slit opening, and a first cavity having a back wall. The plasma confinement system includes a plasma confinement assembly. The plasma confinement assembly has a first magnet disposed in the first cavity adjacent the back wall, and a first window disposed in the first cavity between the first magnet and the inner wall, wherein the first window seals the first magnet from an outside environment.

### BACKGROUND

### FIELD

The embodiments of the disclosure generally relate to the etching or deposition of thin films on substrates in semiconductor chambers. In particular, the disclosure relates to mechanisms for the enhancement of plasma density and uniformity in the semiconductor chamber.

### DESCRIPTION OF THE RELATED ART

Plasma etching can be used in semiconductor processing to fabricate integrated circuits. Integrated circuits can be formed from layer structures including multiple (e.g., two or more) layer compositions. Different etching gas chemistries, e.g., different mixtures of gases, can be used to form a plasma in the processing environment such that a given etching gas chemistry can have increased precision and higher selectivity for a layer composition to be etched. As scaling of integrated circuits continues to move towards smaller features and increased aspect ratios, there is a growing need for precision etching of layer structures.

The uniformity of one or more parameters of the films corresponds to the uniformity of the density of the plasma. Accordingly, any differences in the plasma density from center to edge of the processing volume may cause a variation in one or more parameters of the film or films formed on the substrate. For example, non-uniform plasma density may generate a film having a non-uniform edge-to-edge thickness, which may cause the processed substrate to be unsuitable for use in semiconductor device fabrication. Accordingly, production yields may be reduced, and manufacturing costs may be increased.

Furthermore, with no radial control mechanism on the plasma, the plasma cloud scatters over the entire processing space. The scattered plasma is not effective for the wafer processing. Moreover, energy is wasted by the plasma forming an electrical circuit with the wall instead of the substrate. Thus, energy consumption is increased by the plasma scattering and contacting the chamber wall.

Thus, there remains a need in the art for an improved method of controlling the plasma to increase production throughput while reducing energy consumption.

### SUMMARY

In one embodiment, a plasma confinement system is disclosed for confining a plasma in a processing volume of a processing chamber. The plasma confinement system includes a chamber wall liner having a ring shaped body. The chamber wall liner has an inner wall, a slit opening formed through the inner wall and sized for a substrate to pass therethrough the slit opening, and a first cavity having a back wall. The plasma confinement system includes a plasma confinement assembly. The plasma confinement assembly has a first magnet disposed in the first cavity adjacent the back wall, and a first window disposed in the first cavity between the first magnet and the inner wall, wherein the first window seals the first magnet from an outside environment.

In another embodiment, a plasma processing chamber is disclosed having a plasma confinement system. The processing chamber comprises a lid and a chamber body having a sidewall and a bottom. The lid and chamber body enclosing a processing volume. A substrate support configured to support a substrate within the processing volume. A plasma confinement system having a chamber wall liner. The chamber wall liner having a ring shaped body. The chamber wall liner disposed on the sidewall in the processing volume and surrounding the substrate support. The chamber wall liner has an inner wall, a slit opening formed through the inner wall and sized for a substrate to pass therethrough the slit opening, and a first cavity having a back wall. The plasma confinement system includes a plasma confinement assembly. The plasma confinement assembly has a first magnet disposed in the first cavity adjacent the back wall, and a first window disposed in the first cavity between the first magnet and the inner wall, wherein the first window seals the first magnet from an outside environment.

In another embodiment, a method for processing a substrate is disclosed. The method begins by placing a substrate on a substrate support in a processing volume of a plasma processing chamber having sidewalls. A plasma is generated in the processing volume for processing the substrate. Electromagnets disposed in a sidewall liner generate an electric field from the sidewall into the processing volume of the processing chamber. The plasma is contained over the substrate support by the electric field. The substrate is processed with the plasma contained over the substrate support by the electric field.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional view of a substrate processing system having a plasma confinement system, according to one or more embodiments.

FIG. 2 is a schematic side view of the chamber wall liner and top liner for the substrate processing system of FIG. 1, according to one or more embodiments.

FIG. 3 is a schematic side view of the chamber wall liner having one example of a plasma confinement assembly for shaping the plasma.

FIG. 4 is a detail side view for the plasma confinement assembly.

FIG. 5 is a flow chart of a method for processing a substrate, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Semiconductor devices can be generated by forming one or more films on a substrate. The formed films can include silicon-, nitride-, and oxide-containing films, among others. Processing chambers for processing substrates can be configured to perform etching or chemical vapor deposition (CVD) including plasma-enhanced CVD (PECVD), plasma-enhanced atomic layer deposition (PEALD), or physical vapor deposition (PVD), among other plasma processes. The quality of the films etched on the substrates can be impacted negatively due to the difference, or non-uniformity, of the plasma density or the amount of plasma scatter over a substrate within the processing chamber. The difference in the plasma density within the processing volume of the processing chamber may negatively affect the edge-to-edge uniformity of the films formed on a substrate. Any non-uniformity of the films may result in a drop in production yield, increasing the manufacturing costs of semiconductor devices. Furthermore, the plasma scatter results in excess energy consumption driving up the cost of substrate processing within the processing chamber.

The plasma confinement system and method discussed herein functions to improve the uniformity of plasma density within the processing volume, and in particular, plasma scatter may be reduced significantly. An electromagnet core is disposed within the chamber liner having a plasma facing ceramic window. The electromagnetic core provides a magnetically enhanced restive barrier to the plasma. Thus, the electromagnetic core improves plasma confinement by densifying and consolidating the plasma. Additionally, an angled side gas feed on chamber liner pointing towards the substrate assists promoting plasma density and uniformity.

The decreased dispersion of the plasma within the processing volumes increases the uniformity of the plasma over the substrate. In various embodiments, decreased dispersion of the plasma within the processing volume (e.g., increased densification of the plasma within the processing volume) increases the deposition rate by about 20 percent as compared to conventional processing systems that do not include the plasma confinement system. Further, decreasing the dispersion of the plasma may positively adjust film properties such as the refractive index (n), stress, and extinction coefficient (k), due, in part, to the increased deposition uniformity of formed film. Additionally, the decreased dispersion of the plasma within the processing volumes reduces energy loss from the plasma through the grounded chamber liner. Thus, the apparatus disclosed herein improves process uniformity while reducing the cost of production.

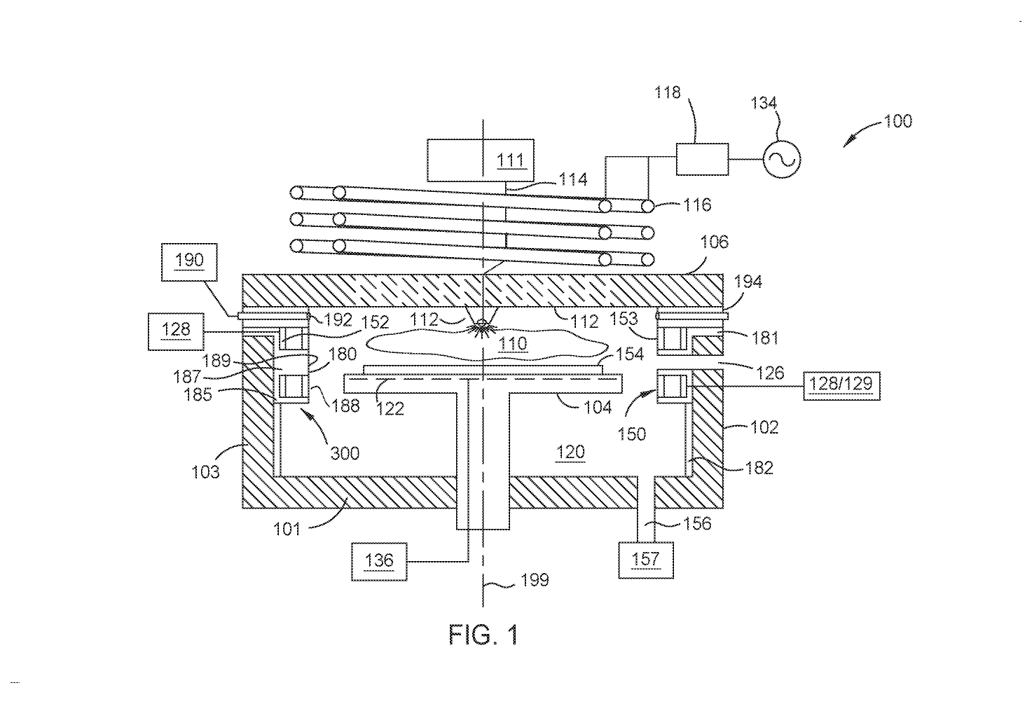

FIG. 1 illustrates a schematic cross-sectional view of a processing chamber 100 having a plasma confinement system 300, according to one implementation described herein. The processing chamber 100 is illustrated as a etch chamber, but the processing chamber 100 may alternatively be another type of plasma enhanced processing chamber. The processing chamber 100 includes a chamber body 102 and a lid 106 disposed on the chamber body 102. The chamber body 102 may include a bottom chamber wall 101 and a chamber sidewall 103. The bottom chamber wall 101, the chamber sidewall 103 and the lid 106 enclose a processing volume 120. A centerline 199 of the processing chamber 100 is equidistant from the chamber sidewall 103 and disposed through the center of the bottom chamber wall 101 and lid 106. While the plasma confinement system 300 of FIG. 1 is illustrate for use in a etch chamber, the plasma confinement system 300 of FIG. 1 may be used with other processing chamber that utilize plasma generated in the processing volume 120.

A substrate support 104 is disposed inside the processing volume 120. The substrate support 104 is centered about the centerline 199. The substrate support 104 is configured to support a substrate 154 thereon during processing. The substrate 154 is transferred into and out of the processing volume 120 through a slit opening 126 formed through the chamber sidewall 103.

The lid 106 includes an injection apparatus 112. The injection apparatus 112 fluidly couples a gas supply source 111 to the processing volume 120.. The injection apparatus 112is coupled via a conduit 114 to the gas supply source 111. The gas supply source 111 supplies process gas through the conduit 114 to the injection apparatus 112. The injection apparatus 112 may be one or more nozzle or inlet ports, or alternatively a showerhead. The nozzle, i.e., injection apparatus 112, has a plurality of openings through which the gas flows out the nozzle into the processing volume 120. In the etch chamber configuration depicted in FIG. 1, the injection apparatus 112 is a nozzle. In other chamber configurations such as a CVD deposition chamber, the injection apparatus 112 may be a showerhead.

The processing gas may be energized to form plasma 110 within the processing volume 120. The processing gas may be energized by capacitively or inductively coupling RF power to the processing gases. In the embodiment depicted in FIG. 1, a plurality of coils 116 are disposed above the lid 106 of the processing chamber 100 and coupled through a matching circuit 118 to an RF power source 134 for inductively coupling the RF power to the processing gas. The RF power source 134 is configured to energize the gas in the processing volume 120 for forming and maintaining a plasma 110.

The gas supply source 111 may include one or more gas sources. The gas supply source 111 is configured to deliver the one or more gases from the one or more gas sources through the injection apparatus 112 to the processing volume 120. Each of the one or more gas sources provides a processing gas (such as argon, hydrogen or helium) that may be ionized to for plasma formation. For example, one or more of a carrier gas and an ionizable gas may be provided into the processing volume 120 along with one or more precursors. When processing the substrate 154, the processing gases are introduced to the processing chamber 100 at a flow rate from about 6500 sccm to about 8000 sccm, from about 100 sccm to about 10,000 sccm, or from about 100 sccm to about 1000 sccm. Alternatively, other flow rates may be utilized. In some examples, a remote plasma source can be coupled to the gas supply source 111 and be used to deliver reactive species into the processing chamber 100.

An exhaust port 156 is coupled to a vacuum pump 157 and is disposed along the wall of the processing chamber 100. The vacuum pump 157 removes excess process gases or by-products from the processing volume 120 during and/or after processing via the exhaust port 156.

The substrate support 104 contains or is formed from a metal or ceramic material. Exemplary ceramic materials include one or more metals, metal oxides, metal nitrides, metal oxynitrides, or any combination thereof. For example, the substrate support 104 may be formed from a metal aluminum or a ceramic such as aluminum oxide, aluminum nitride, aluminum oxynitride, or any combination thereof.

An electrode 122 is embedded within the substrate support 104, but may alternatively be coupled to a surface of the substrate support 104. The electrode 122 is coupled to a power source 136. The power source 136 is configured to provide DC power, pulsed DC power, radio frequency (RF) power, pulsed RF power, or any combination thereof to the electrode 122. The power source 136 drives the electrode 122 with a drive signal that energizes the plasma within the processing volume 120. The drive signal may be one of a DC signal and a varying voltage signal (e.g., RF signal).

Plasma 110 is maintained in the processing volume 120 via inductive coupling to the RF power supplied by the RF power source 134. An RF field is created by driving at least one of the top electrode, i.e., coils 116, and the electrode 122 with drive signals to facilitate the formation of a capacitive plasma within the processing volume 120. The presence of a plasma facilitates processing of the substrate 154, for example, etching of a film on a surface of the substrate 154.

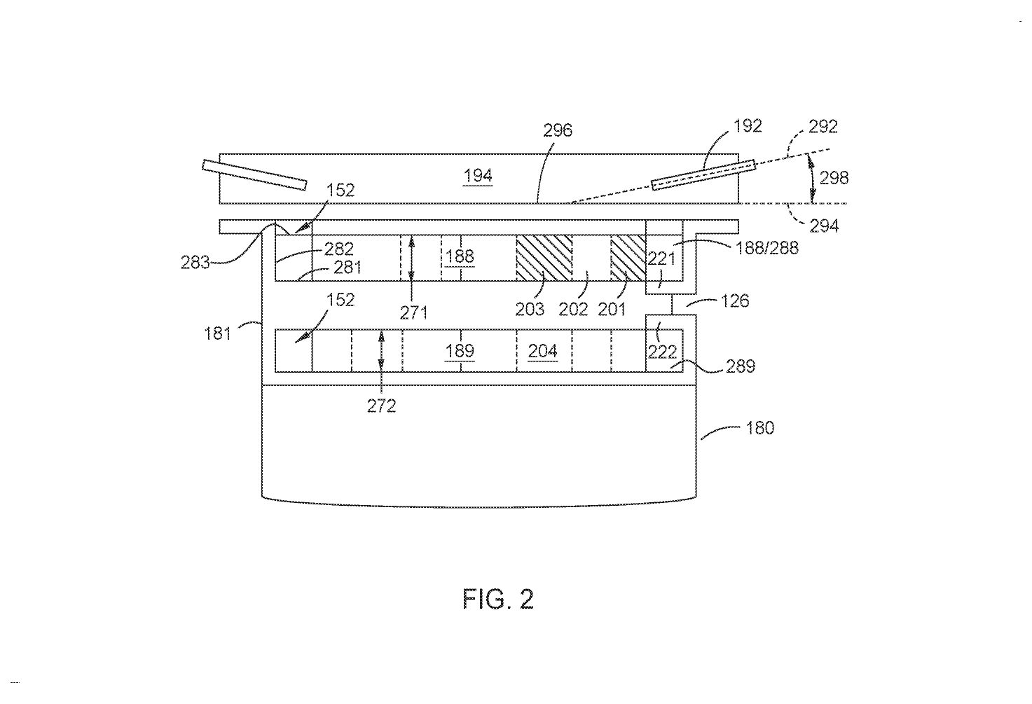

A top liner 194 is disposed adjacent to the chamber body 102 and separates the chamber body 102 from the lid 106. In one example, a bottom surface 296 (shown in FIG. 2) of the top liner 194 rests on the chamber body 102. The top liner 194 may be part of the lid 106, but may alternately be separate from the lid 106. The top liner 194 may be an annular, or ring-like member, and may include one or more side gas feed nozzles 192. The side gas feed nozzle 192 is coupled to a side gas supply 190. In one example, the top liner 194 has eight side gas feed nozzles 192. The side gas feed nozzles 192 may be oriented to inject a gas parallel to the injection apparatus 112. Alternately, the side gas feed nozzles 192 may be angled downward away from the injection apparatus 112 to inject a gas inward toward the centerline 199 and away to the injection apparatus 112. For example, as shown in FIG. 2, the side gas feed nozzles 192 may have a center line 292 that is offset by an angle 298 form a plane 294 of the bottom surface 296 of the top liner 194. In one example, the angle 298 between the center line 292 of the side gas feed nozzles 192 and the plane 294 is between about 0 degrees and about 45 degrees, such as about 10 degrees. In this manner, gas flowing through the side gas feed nozzles 192 is directed inward at the plasma 110. In one example, the side gas feed nozzles 192 helps confine the plasma 110 about the centerline 199 in the processing volume 120 and above the substrate support 104. The angle 298 of the side gas feed nozzles 192 pointing towards the substrate 154 assists in densifying the plasma 110 and improving process uniformity.

The plasma confinement system 300 includes a chamber wall liner 180 and a plasma confinement assembly 150. The plasma confinement system 300 may additionally include the one or more side gas feed nozzles 192 discussed above. The chamber wall liner 180 is particularly configured for use with the plasma confinement assembly 150. That is, the chamber wall liner 180 may be provided with the plasma confinement assembly 150.

The chamber wall liner 180 is ring shaped and may be disposed on the chamber sidewall 103 in the chamber body 102. The chamber wall liner 180 has an inner wall 189. The inner wall 189 being the innermost wall of the chamber wall liner 180 and facing the processing volume 120 of the processing chamber 100. The chamber wall liner 180 is disposed between the chamber sidewall 103 and the processing volume 120. The slit opening 126 extends through the chamber wall liner 180 and the inner wall 189 to provide access to the processing volume 120. The chamber wall liner 180 is replaceable and is made from a material configured to protect the chamber sidewall 103 from the plasma 110. The chamber wall liner 180 may also typically be grounded to a common ground of the processing chamber 100.

The chamber wall liner 180 has one or more confinement cavities 188 therein. The one or more confinement cavities 188 extends through the inner wall 189 of the chamber wall liner 180. The confinement cavities 188 is sized and configured for the plasma confinement assembly 150 to be disposed therein. The plasma confinement assembly 150 alters the density of the plasma 110 and shapes and/or moves the plasma 110 with respect to the chamber wall liner 180 and substrate support 104.

The chamber wall liner 180 may optionally extend between the chamber body 102 and the top liner 194. The chamber wall liner 180 includes an upper wall liner 181 and a lower wall liner 182. The upper wall liner 181 may extend above the slit opening 126. The lower wall liner 182 extends from the upper wall liner 181 to the bottom 101 of the chamber body 102. In one example, the upper wall liner 181 and lower wall liner 182 are monolithic, i.e., of a single solid piece of material.

The lower wall liner 182 is ring shaped and may generally be formed from a ceramic material. In one embodiment, the lower wall liner 182 is formed from AlN, Al₂O₃ or other suitable materials. The lower wall liner 182 may be coated, for example, with yttria or other material. The lower wall liner 182 may be of a substantially consistent thickness. In one example, the lower wall liner 182 may be part of the upper wall liner 181 as a single piece chamber wall liner 180. In another example, the lower wall liner 182 may be separate from the upper wall liner 181 forming a two piece chamber wall liner 180.

The upper wall liner 181 will now be discussed with further reference to FIG. 2. FIG. 2 is a schematic side view of the chamber wall liner 180 and top liner 194 for the substrate processing system 100 of FIG. 1. The upper wall liner 181 may generally be formed from a ceramic material. In one embodiment, the upper wall liner 181 is formed from AlN, Al₂O₃ or other suitable materials. The upper wall liner 181 may be coated, for example, with yttria or other material. The upper wall liner 181 may have a top portion 193 extending over a top portion of the body 102 and be in contact between the body 102 and the top liner 194.

The upper wall liner 181 has a first cavity 288 of the one or more confinement cavities 188. In one example, the top portion 193 of the upper wall liner 181 may extend over and form a top 283 of the first cavity 288. In this arrangement, the upper wall liner 181 at the first cavity 288 may be “U” shaped. Alternately, the bottom surface 296 of the top liner 194 forms the top 283 of the first cavity 288. In this arrangement, the upper wall liner 181 at the first cavity 288 may be “L” shaped. The first cavity 288 is disposed above the slit opening 126 in the chamber sidewall 103. Additionally, the first cavity 288 is configured to be above a plane of the substrate support 104. The top 283 and bottom wall 281 may be substantially the same length and sized to accommodate the plasma confinement assembly 150 for shaping plasma therein the first cavity 288 without extending beyond the inner wall 189.

The first cavity 288 may have a rectangular shape. In one example, the first cavity 288 has a back wall 282 and a bottom wall 281 formed from the upper wall liner 181. That is, the back wall 282 and bottom wall 281 are part of the upper wall liner 181. The first cavity 288 has a first height 271 measured between the bottom wall 281 and the upper wall liner 181. The first height 271 of the first cavity 288 is configured to accommodate one or more aspects of the plasma confinement assembly 150 therein. In one example, the first height 271 is between about 3.0 inches and about 5.0 inches, such as about 4.0 inches. It should be appreciated that the shape and size of the first cavity 288 may be any suitable shape, for example, trapezoidal.

The first cavity 288 has an open end 216 exposed to the processing volume 120. In one example, the first cavity 288 extends horizontally and continuously around the upper wall liner 181 in a ring shape. In another example, the first cavity 288 extends horizontally around the upper wall liner 181 in a ring shape as a series of intermittent openings 202 spaced from each other by an intermediary walls 201/203. The intermittent openings 202 may be equally spaced apart by the intermediary walls 201/203 to balance the spatial uniformity of the intermittent openings 202 along the ring shape of the first cavity 288.

The lower wall liner 182 may optionally have a second cavity 289 of the one or more confinement cavities 188. The second cavity 289 may be substantially similar to the first cavity 288 in shape and function. The second cavity 289 may be formed in the lower wall liner 182 below the slit opening 126. The second cavity 289 may have a second height 272 smaller than the first height 271 of the first cavity 288. Alternately, the second cavity 289 may have a second height 272 substantially similar to that of the first height 271 of the first cavity 288. The second cavity 289 is configured to accommodate one or more aspects of the plasma confinement assembly 150 therein. In one example, the second height 272 of the second cavity 289 is between about 2.0” and about 4.0”, such as about 3.0”.

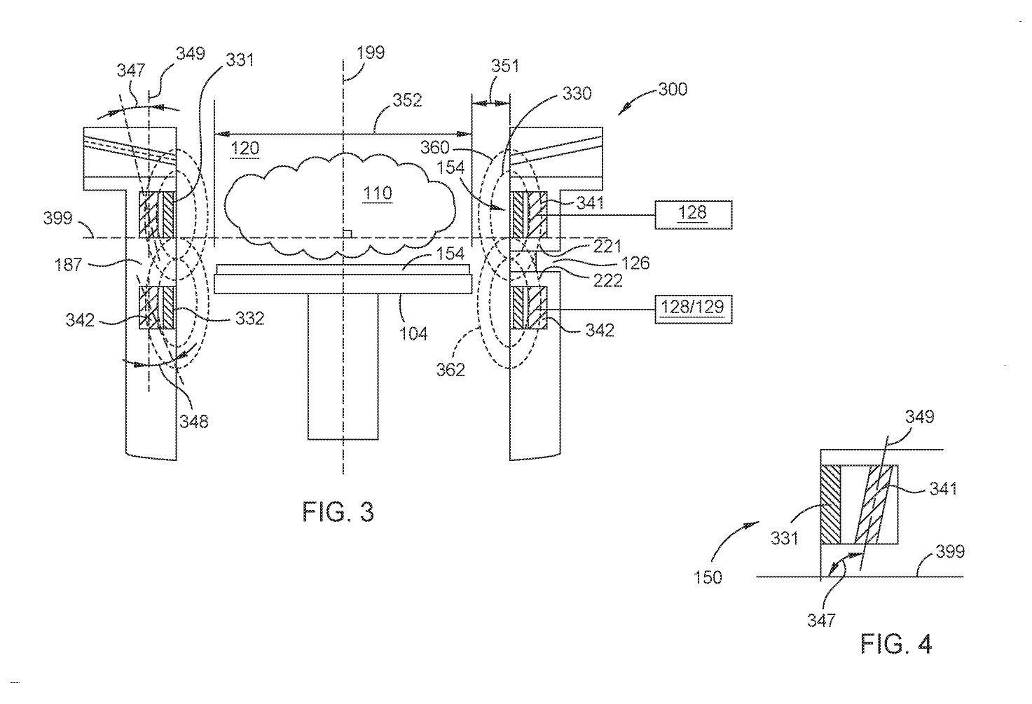

The chamber wall liner 180 will be discussed further with respect to FIG. 3. FIG. 3 is a schematic side view of the chamber wall liner 180 having one example of the plasma confinement assembly 150 for shaping the plasma 110. The plasma confinement assembly 150 disposed in the first cavity 288 has a magnet 152 and an optical window 153. The magnet 152 may be an electromagnet coupled to a first power source 128. The optical window 153 shields the magnet 152 from the processing chamber environment while allowing a magnetic field of the magnet 152 to penetrate through the optical window 153 into the processing volume 120. The optical window 153 may be quartz or other suitable material.

The magnet 152 may include a first electromagnet 341. The optical window 153 may include a first optical window 331. The first optical window 331 is sealingly disposed along the inner wall 189 of the chamber wall liner 180. For example, the first electromagnet 341 is hermetically sealed in the first cavity 288 by the first optical window 331. In this manner, the first electromagnet 341 is protected from process gases and plasma in the processing volume 120 of the processing chamber 100.

In one example, the first electromagnet 341 is ring shaped. For example, the first electromagnet 341 is formed or wound in a continuous ring shape concentric with the first cavity 288 and centered about the centerline 199. In another example, the first electromagnet 341 includes a plurality of electromagnets, or segments, formed or placed in the shape of a ring. In one example, the first electromagnet 341 is formed as three or more distinct segments with each segment of the first electromagnet 341 spaced apart from an adjoining segment. For example, each segment of the first electromagnet 341 may reside separately in a respective intermittent opening 202. In another example, each segment of the first electromagnet 341 may be placed adjacent each other in the continuous ring concentric with the first cavity 288 about the centerline 199 without the intermediary walls 201/203.

The first electromagnet 341 is coupled to the first power source 128. The first electromagnet 341, when powered by the first power source 128, creates a first B-field 360 which moves the plasma 110 away from the first electromagnet 341. The ring shape of the first electromagnet 341 pushes the plasma 110 away from the chamber wall liner 180 a distance 351 to confine the plasma 110 to a space 352 over the substrate support 104. In one example, the distance 351 is substantially similar for the plasma 110 from the chamber wall liner 180 as the distance for the substrate support 104 to the chamber wall liner 180. Likewise, the space 352 in which the plasma 110 is centered about the centerline 199 may be substantially similar to a width of the substrate support 104.

Similarly, the plasma confinement assembly 150 may optionally be disposed in the second cavity 289. The plasma confinement assembly 150 in the second cavity 289 has a second electromagnet 342 and a second optical window 332. The second electromagnet 342 and the second optical window 332 are substantially similar to and operate in a manner similar to the first electromagnet 341 and the first optical window 331. For example, the second electromagnet 342 may be segmented or continuous. In this manner, the plasma can be further confined to remain above the substrate support 104.

The second electromagnet 342 is coupled to the first power source 128. Alternately, the second electromagnet 342 is coupled to a second power source 129. The second electromagnet 342, when powered by either the first power source 128 or second power source 129, creates a second B-field 362 which moves the plasma 110 away from the second electromagnet 342. The ring shape of the electromagnets push the plasma 110 away from the chamber wall liner 180 and above the substrate support 104 to maintain the plasma 110 over the substrate support 104.

In operation, the first B-field 360 creates a restive barrier to the plasma 110 which confines the plasma 110 to the space 352 above the substrate support 104. The distance 351 between the plasma 110 from the chamber wall liner 180 is sufficiently large to decrease the potential between the chamber wall liner 180 and the plasma 110 for preventing arcing or excess power consumption. When additionally applied, the second B-field 362 further prevents the plasma 110 from extending below the substrate support 104. Thus, the plasma confinement assembly 150 densifies and consolidates the plasma 110 to improve non-uniformity of the plasma films deposited during production. Furthermore, the scatter of the plasma 110 is minimized to prevent excess energy consumption and reduced the cost of substrate processing within the processing chamber.

FIG. 4 is a detail side view for the plasma confinement assembly 150. The plasma confinement assembly 150 is shown as the first electromagnet 341 and the first optical window 331 disposed in the confinement cavities 188. However, it should be understood that the following discussion relates additionally to the second electromagnet 342. The first electromagnet 341 has a magnetic axis 349. The North Pole and South Pole of the first electromagnet 341 may reside on the magnetic axis 349. The first B-field 360 lines are nearly vertical at each magnetic pole and travel in a continuous, i.e., closed loop, centered on the magnetic axis 349.

The strength of the first B-field 360 is a function of distance. Thus, by tilting, moving, or rotating the magnetic axis 349 of the first electromagnet 341, the strength of the first B-field 360 in the processing volume 120 can be changed (i.e., selected). A perpendicular 399 to the centerline 199 of the processing chamber 100 can be used to describe an angle 347 for orienting the magnetic axis 349 of the first electromagnet 341 and thus shaping the first B-field 360. As shown in FIG. 3, the angle 347 of the first electromagnet 341 is about 90° to the perpendicular 399. In one example, the angle 347 of the magnetic axis 349 may be between about 70° and about 110°. For example, the angle 347 may be greater than about 90°, such as an angle 347 about 94°. Similarly, the magnetic axis of the second electromagnet 342 can be tilted to adjust the shape of the second B-field 362.

The first B-field 360 has an oblong shape which tappers back at the poles of the magnetic axis 349. The orientation of the magnetic axis 349 causes the first B-field 360 shape in the processing volume 120 to substantially be vertically aligned with an edge of the substrate 154. The first B-field 360 thus tightly aligns the outer periphery of the plasma 110 with the substrate 154. In this manner, greater control of the plasma 110 density and location can be made. It should be appreciated that the angle 347 of the first electromagnet 341 may not be the same as the angle of the second electromagnet 342. For example, the magnetic axis 349 of the first electromagnet 341 may be at about 94° to the perpendicular 399 while the magnetic axis of the second electromagnet 341 may be at about 90° to the perpendicular 399.

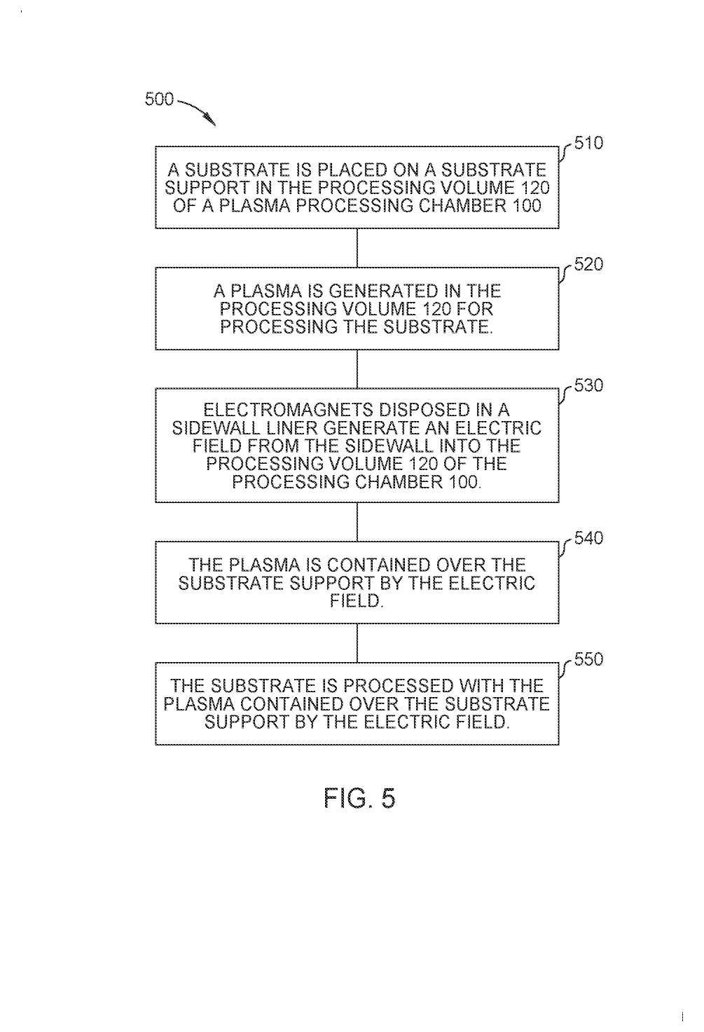

Using the plasma confinement system 300 discussed above, the uniformity of the density of the plasma 110 within the processing volume 120 is improved significantly. FIG. 5 is a flow chart of a method 500 for processing the substrate 154, according to one or more embodiments. The method 500 may be employed to form one or more films on the substrate 154. At operation 510, a substrate is placed on the substrate support 104 in the processing volume 120 of a plasma processing chamber 100 capable of performing CVD and/or PECVD. For example, the substrate 154 may be positioned within the processing chamber 100 to form the one or more low-k films on the substrate 154.

At operation 520, the plasma 110 is generated in the processing volume 120 for processing the substrate 154. For example, one or more process gases may be introduced by the gas supply source 111 to the processing chamber 100 to deposit a low-k film on the substrate. The process gases may include at least one precursor gas, ionizable gas and carrier gas, and one or more of the processing gases may be ionized to form a plasma. The electrode 122 may be driven with an RF signal by the power source 136 to ionize the processing gas or gases into forming and maintaining the plasma 110. Further, the precursor gas may be utilized to form a film on the substrate 154 in the presence of the plasma 110.

In some examples, the one or more deposition precursors includes a silicon-containing component, in which a silicon atom is bonded to at least one of a carbon atom and/or an oxygen atom. In at least one embodiment, the silicon containing component may include any one or more silicon based compound, such as trimethylsilane, triethoxysilane, methyldiethoxysilane, dimethylethoxysilane, dimethylmethoxysilane, methyldimethoxysilane, dimethyldisiloxane, tetramethyldisiloxane, 1,3-bis(silanomethylene)disiloxane, bis(1-methyldisiloxanyl)methane, bis(1-methyldisiloxanyl)propane, and combinations thereof. Additionally or alternatively, the one or more deposition precursors may include one or more compounds containing carbon or an oxygen.

In some embodiments, which may be combined with other embodiments, the deposition precursor may be introduced to the process chamber 100 while maintaining the temperature of the substrate and/or process chamber at about 100 °C to about 450 °C, e.g., about 100 °C to about 400 °C, about 150 °C to about 350 °C, about 200 °C to about 350 °C, or about 250 °C to about 350 °C. The deposition precursor may be introduced to the process chamber 100 while maintaining a pressure of about 0.5 Torr to about 500 Torr, such as about 3 Torr to about 80 Torr, such as about 3 Torr to about 60 Torr, such as about 3 Torr to about 50 Torr, such as about 3 Torr to about 40 Torr, or such as about 3 Torr to about 5 Torr. The spacing between a substrate support and the injection apparatus may be between about 100 mils and about 1500 mils, such as between about 200 mils and about 1000 mils.

The deposition precursor may be introduced to the process chamber 100 at a flow rate of about 10 milligrams per minute (mgm) to about 3000 mgm, such as about 100 mgm to ab out 2000 mgm, such as about 300 mgm to about 2000 mgm, such as about 1000 mgm to about 2000 mgm. Optionally, a carrier gas, e.g., helium, argon, krypton, neon, or a combination thereof, may additionally be provided to the process chamber. For example, the carrier gas can include helium, argon, or combinations thereof. The carrier gas may be flowed into the processing chamber at a constant flow rate of about 50 (standard cubic centimeters per minute) sccm to about 5,000 sccm, e.g., about 100 sccm to about 4,000 sccm, about 500 sccm to about 2,500 sccm, or about 1,000 sccm to about 1,500 sccm.

In some embodiments, which may be combined with other embodiments, a reactive gas, e.g., oxygen, may additionally be provided to the process chamber. The reactive gas includes oxygen containing compounds selected from the group of oxygen (O₂), nitrous oxide (N₂O), ozone (O₃), water (H₂O), carbon dioxide (CO₂), carbon monoxide (CO), and combinations thereof. The reactive gas may be flowed into the processing chamber at a constant flow rate of about 0 sccm to about 500 sccm, e.g., about 10 sccm to about 400 sccm, about 50 sccm to about 250 sccm, or about 100 sccm to about 150 sccm.

The deposition precursor may be introduced to the process chamber, in which a RF bias power may be applied to the substrate support at a frequency of about 10 Hz to about 15 MHz, e.g., about 100 Hz to about 100,000 Hz, about 1,000 Hz to about 100,000 Hz, about 10,000 Hz to about 100,000 Hz, or about 1 MHz to about 13 Mhz, may be applied to maintain a plasma in the processing volume. In some embodiments, the RF bias power may include a power of about 50 W to about 1000 W, e.g., about 100 W to about 900 W, about 200 W to about 800 W, about 300 W to about 700 W, about 400 W to about 600 W, or about 450 W to about 550 W.

At operation 530, electromagnets disposed in the chamber wall liner 180 generate an electric field from the chamber wall liner 180 into the processing volume 120 of the processing chamber 100. For example, the first electromagnet 341 of the plasma confinement assembly 150 disposed in the first cavity 288 of the chamber wall liner 180 may be energized by the first power source 128. In another example, the second electromagnet 342 of the plasma confinement assembly 150 disposed in the second cavity 289 of the chamber wall liner 180 may be energized by the first power source 128. Alternately, the second electromagnet 342 is energized by the second power source 129.

At operation 540, the plasma is contained over the substrate support by the electric field. The energized first electromagnet 341 creates the first B-field 360 to confine the plasma over the substrate support 104. In another example, the power to the first electromagnet 341 is changed to change the size of the first B-field 360. In yet another example, the first electromagnet 341 is tilted to change the shape of the first B-field 360. The magnetic axis 349 of the first electromagnet 341 may be tilted between about 70 degrees and about 110 degrees. For example, the magnetic axis 349 of the first electromagnet 341 is tilted greater than 90 degrees, such as 94 degrees. In this manner, the plasma 110 scatter can be reduced and deposition can be improved with greater plasma density.

The second electromagnet 342 may optionally be energized to create the second B-field 362 to confine the plasma above the substrate support 104. In another example, the power to the second electromagnet 342 is changed to change the size of the second B-field 362. The second electromagnet 342 is separately controlled from the first electromagnet 341. In one example, the first electromagnet 341 is powered on while the second electromagnet 342 is powered off. In another example, the first electromagnet 341 is powered on while the second electromagnet 342 is powered on. In yet another example, the first electromagnet 341 is powered on to generate a first B-field 360 while the second electromagnet 342 is powered on to generate a smaller second B-field 362. In yet another example, the magnetic axis 349 of the first electromagnet 341 is tilted with respect to the magnetic axis of the second electromagnet 342. The tilted magnetic axis 349 vertically aligns the first B-field 360 in the processing volume 120 for tightly controlling the plasma 110.

At operation 550, the substrate is processed with the plasma contained over the substrate support by the electric field. The first B-field 360 is relied on to keep the plasma 110 away from the chamber wall liner 180 and densify the plasma 110 over the substrate. The increase in the uniformity and density of the plasma enhances the plasma quality resulting in increased deposition rate of a corresponding film, improving one or more parameters of the film, and reduction of power lost to the plasma contacting the grounded chamber wall liner 180. Accordingly, the edge-to-edge uniformity of one or more parameters of a film formed on the substrate 154 is also increased. For example, the edge-to-edge uniformity of a thickness of the film may be increased.

A resulting low-k film is deposited onto the substrate. The film has a thickness of greater than about 500 Å. In some embodiments, the resulting low k films deposited onto the substrate have a thickness of about 1000 Å to about 4000 Å.

Advantageously, the plasma confinement assembly 150 decreases dispersion of the plasma within the processing volumes for increased the uniformity of the plasma over the substrate. Furthermore, the tilting of the magnets in the plasma confinement assembly 150 provides greater directional control for condensing and locating the plasma 110 over the substrate 154 in the processing volume 120. The directional control and decreased dispersion of the plasma 110 increases the deposition rate by about 20 percent. Further, decreasing the dispersion of the plasma positively adjust film properties such as the refractive index (n), stress, and extinction coefficient (k), due, in part, to the increased deposition uniformity of the formed film on the substrate 154. Additionally, the decreased dispersion of the plasma 110 within the processing volumes 120 reduces energy loss from the plasma 110 through the chamber wall liner 180 reducing the cost of production.

While the foregoing is directed to embodiments of the present disclosure, other and further embodiments of the disclosure may be devised without departing from the basic scope thereof, and the scope thereof is determined by the claims that follow.

What is claimed is:

1. A plasma confinement system comprising:
a chamber wall liner having a ring shaped body and disposed about a centerline, the chamber wall liner comprising:
an inner wall,
a slit opening formed through the inner wall, the slit opening sized to allow a substrate to pass therethrough:
a first cavity having a first back wall; and
a plasma confinement assembly comprising:
a first magnet disposed in the first cavity adjacent the first back wall; and
a first window disposed in the first cavity between the first magnet and the inner wall, wherein the first window seals the first magnet within the first cavity.

2. The plasma confinement system of claim 1, wherein the chamber wall liner further comprises:
an upper wall liner having the first cavity, wherein the upper wall liner is disposed above the slit opening; and
a lower wall liner disposed below the slit opening.

3. The plasma confinement system of claim 2, wherein the upper wall liner and the lower wall liner are monolithic and formed of a single solid piece of material.

4. The plasma confinement system of claim 2, wherein the upper wall liner and the lower wall liner are two separate pieces.

5. The plasma confinement system of claim 2, wherein the lower wall liner further comprises:
a second cavity having a second back wall, wherein the plasma confinement assembly further comprises:
a second magnet disposed in the second cavity adjacent the second back wall; and
a second window disposed in the second cavity between the second magnet and the inner wall, wherein the second window seals the second magnet within the second cavity.

6. The plasma confinement system of claim 1, wherein the first magnet is tilted at an angle greater than 90° relative to a perpendicular to the centerline.

7. The plasma confinement system of claim 1, wherein the first magnet is hermetically sealed in the first cavity.

8. A processing chamber comprising:
a lid;
a chamber body having a sidewall and a bottom disposed about a centerline, the chamber body having and lid enclosing a processing volume;
a substrate support configured to support a substrate within the processing volume; and
a plasma confinement system comprising:
a chamber wall liner having a ring shaped body, the chamber wall liner disposed on the sidewall in the processing volume and surrounding the substrate support, the chamber wall liner comprising:
an inner wall,
a slit opening formed through the inner wall and sized to allow a substrate to pass therethrough; and
a first cavity having a back wall; and
a plasma confinement assembly comprising:
a first magnet disposed in the first cavity adjacent the back wall; and
a first window disposed in the first cavity between the first magnet and the inner wall, wherein the first window seals the first magnet within the first cavity.

9. The processing chamber of claim 8, wherein the chamber wall liner further comprises:
an upper wall liner having the first cavity, wherein the upper wall liner is disposed above the slit opening; and
a lower wall liner disposed below the slit opening.

10. The processing chamber of claim 9, wherein the upper wall liner and the lower wall liner are monolithic and formed of a single solid piece of material.

11. The processing chamber of claim 9, wherein the upper wall liner and the lower wall liner are two separate pieces.

12. The processing chamber of claim 9, wherein the lower wall liner further comprises:
a second cavity having a second back wall, wherein the plasma confinement assembly further comprises:
a second magnet disposed in the second cavity adjacent the second back wall; and
a second window disposed in the second cavity between the second magnet and the inner wall, wherein the second window seals the second magnet within the second cavity.

13. The processing chamber of claim 8, wherein the first magnet is tilted at an angle greater than 90° relative to a perpendicular to the centerline.

14. The processing chamber of claim 8, wherein the first magnet is hermetically sealed in the first cavity.

15. A method for forming a film, the method comprising:
placing a substrate on a substrate support in a processing volume of a plasma processing chamber having a sidewall and a sidewall liner disposed on the sidewall in the processing volume;
generating a plasma in the processing volume for processing the substrate;
generating, with first electromagnets disposed in a first cavity of the sidewall liner disposed above the substrate support, a first electric field that extends from the sidewalls into the processing volume of the processing chamber;
containing the plasma over the substrate support by the first electric field; and
processing the substrate with the plasma contained over the substrate support by the first electric field.

16. The method of claim 15, wherein the first electromagnets disposed in the sidewall liner are hermetically sealed in the first cavity of the sidewall liner by a first window.

17. The method of claim 15, further comprising:
tilting the first electromagnets, wherein an orientation of a magnetic axis of the first electromagnet causes the first electric field in the processing volume to substantially be vertically aligned with an edge of the substrate.

18. The method of claim 17, wherein the first electromagnets are disposed in the sidewall liner above a slit valve opening.

19. The method of claim 17, further comprising:
generating, with second electromagnets disposed in a second cavity of the sidewall liner, a second electric field that extends from the sidewalls into the processing volume of the processing chamber, wherein the second cavity is disposed below the substrate support.

20. The method of claim 19, wherein the second electromagnets is separately controlled from the first electromagnets.
